(19) United States
(12) Patent Application Publication
(10) Pub. No.: US 2010/0087024 A1
(43) Pub. Date: Apr. 8, 2010

(54) DEVICE CAVITY ORGANIC PACKAGE STRUCTURES AND METHODS OF MANUFACTURING SAME

(76) Inventors: Noureddine Hawat, Woburn, MA (US); Peter R. Nuytkens, Melrose, MA (US)

Correspondence Address: GOODWIN PROCTER LLP;PATENT ADMINISTRATOR, 53 STATE STREET, EXCHANGE PLACE, BOSTON, MA, 02109-2881, US

(21) Appl. No.: 12/488,137

(22) Filed: Jun. 19, 2009

Related U.S. Application Data
(60) Provisional application No. 61/074,045, filed on Jun. 19, 2008.

(51) Int. Cl. H01L 21/98

(52) U.S. Cl. 438/51; 257/E21.705

(57) ABSTRACT

Structured and Methods for integrating MEMS devices into low-cost organic chip-scale packages, using sealed cavities, are provided.

### CROSS-REFERENCE TO RELATED APPLICATION

This application claims priority to and the benefit of U.S. Provisional Application No. 61/074,045, filed on Jun. 19, 2008, the entire disclosure of which is hereby incorporated herein by reference.

### FIELD OF INVENTION

The present invention relates, generally, to the packaging of semiconductor devices and, more specifically, to the sealing of microelectromechanical systems (MEMS) devices under controlled vacuum or pressure.

### BACKGROUND OF INVENTION

The successful application of MEMS technology depends largely on cost-effective means for integrating MEMS devices into chip-scale packages. MEMS packaging often involves integrating MEMS devices into hermetically sealed cavities. The hermetic cavity serves to protect fragile mechanic structures from damage, and to provide a controlled environment, in particular, for MEMS sensors. Methods that yield hermetic seals in chip scale packages include glass-frit sealing, laminated-epoxy sealing, metal sealing, and polymer laser sealing.

Glass-frit sealing is often used in conventional hermetic ceramic packages. The glass frit seals the cavity walls between a cap and the device walls. The cap, walls, or both can be made of metal or ceramic. Either the cap or walls are stenciled with a mixture of glass and binder. Firing the cap sinters the stenciled glass onto the cap. The cap is aligned with and placed on the cavity, and then thermo-compression-bonded to the cavity, thereby creating the hermetic seal. A reliable glass frit thermo-compression seal needs a large bonding for the glass frit seal, and requires the substrate or walls to be of sufficient mass to withstand the thermo-compression bond. This approach can achieve a hermetic seal meeting the requirements of MIL STD 883, but bears the disadvantages of a large foot print and a high thickness of the cap.

For laminated-epoxy sealing, an epoxy seal ring is either dispensed on, or preformed and then applied to, the lid, the walls of the cavity, or both. The epoxy cap or walls can be made of glass, ceramic or metal. The epoxy is cured by heat and/or pressure. The resulting cured epoxy ring limits the hermetic seal to that of quasi-hermetic or near-hermetic performance. The hermetic seal properties are dependent on the ratio of the exposed cross-sectional area of the seal to the cross-section area of the cavity, on the pressure of the enclosed gas in the cavity, as well as on the composition of the epoxy. Permeability and adhesive out-gassing set the limits on the achievable hermeticity and vacuum levels.

Metal sealing employs a cap and wafer cap joined with a gold cold-welded hermetic seal. The seal gasket encloses the perimeter of the cap and walls. The gasket height is determined by plating and assembly pressure. The cap is aligned with the walls, and sealed by compression and exposure to high temperature. If the cap is soldered or sealed at low temperature, later soldering to mount the device on the end-customer's board could cause the cap to melt, and change the ambient pressure inside the package (e.g., from high pressure to low pressure, or from vacuum to air), which will result in damage to the device and, consequently, in impaired sensitivity and functionality.

To obtain a molded polymeric laser seal, the cap and walls are formed by Liquid Crystal Polymer (LCP), a thermoplastic with barrier properties that are an order of magnitude better than those of epoxy materials. The cap and wall are aligned, and an infrared laser is applied. The laser light penetrates through the cap and heats the non-transparent metal, which, in turn, melts the seal.

### SUMMARY OF INVENTION

In various embodiments, the present invention provides low-cost methods for the integration of MEMS devices in hermetically sealed cavities into chip-scale organic packages. The packages may be based on high glass transition temperature multi-layer organic laminated substrates. To integrate a MEMS device, generally, a hole is formed in the substrate, the MEMS device is placed over one side of the hole, a cap is placed over the other side of the hole, and the cavity thereby formed is sealed.

More particularly, in a first aspect, the invention provides a method for integrating a MEMS device into an organic chip scale package by providing a high glass transition temperature multi-layer organic laminated substrate; forming a cavity hole through the substrate; soldering a cap to a first side of the substrate over the cavity hole; then placing the MEMS device on a second side of the substrate under the cavity hole, thereby forming a cavity; and, finally, sealing the cavity. The hole may be formed by routing, laser cutting, and/or punching through a patterned metal ring. Soldering may be accomplished by reflow-soldering at a temperature in the range from about 260° C. to about 340° C. Before the MEMS device is placed, solder paste may be applied to the second side of the substrate.

In some embodiments, the method further includes edge-plating a metal layer onto an edge surface of the cavity hole and, optionally, plating a second metal layer onto the edge surface at a second side of the substrate. Sealing the cavity may include dispensing a liquid crystal polymer or a low-outgassing epoxy around an edge of the MEMS device. Alternatively, before the cavity is sealed, a preformed crystal polymer ring or low-outgassing epoxy ring may be placed around the hole on the second side of the substrate. Similarly, a preformed crystal polymer ring or low-outgassing epoxy ring may be placed on the first side of the substrate. In certain embodiments, the cavity is evacuated. In alternative embodiments, the cavity is pressurized with a selected pressurized gas.

In a second aspect, the invention provides, in various embodiments, a method for integrating a micro-electromechanical sensor (MEMS) device into an organic chip scale package by providing a high glass transition temperature multi-layer organic laminated substrate; forming a cavity hole through the substrate; soldering the MEMS device to a one side of the substrate under the cavity hole; then placing a cap on the other side of the substrate over the cavity hole, thereby forming a cavity; and, finally, sealing the cavity. The MEMS device, after being soldered to the substrate, may be underfilled with a low-outgassing epoxy or a liquid crystal polymer. Further, before the cap is placed on the other side, the substrate and MEMS device may be cleaned using oxygen plasma ashing. The cavity may be evacuated or, alternatively, pressurized with a selected cavity gas.

### BRIEF DESCRIPTION OF DRAWINGS

The foregoing discussion will be understood more readily from the following detailed description of the invention when taken in conjunction with the accompanying drawings, in which:

FIG. 1 is a schematic cross section of a package structure with an integrated MEMS device in accordance with one embodiment of the invention;

FIG. 2 is an illustration of substrate artwork that may be used in various embodiments of the invention;

FIG. 3 is a schematic cross section of a package structure with an integrated MEMS device in accordance with another embodiment of the invention;

FIG. 4 is a schematic top view of a substrate patterned with frame artwork for an array of device structures in accordance with various embodiments of the invention;

FIG. 5 is a schematic drawing showing top and side views of a cap in accordance with some embodiments of the invention;

FIG. 6 is a flow chart illustrating a method for integrating a MEMS device into a package structure in accordance with some embodiments of the invention;

FIG. 7 is a flow chart illustrating an alternative method for integrating a MEMS device into a package structure in accordance with some embodiments of the invention;

FIG. 8 is a schematic drawing illustrating, in cross section, a patterned substrate in accordance with various embodiments of the invention;

FIG. 9 is a schematic drawing illustrating, in cross section, the formation of a hole in the substrate of FIG. 8;

FIG. 10 is a schematic drawing illustrating, in cross section, die and frame placement and soldering to the substrate of FIG. 9;

FIG. 11 is a schematic drawing illustrating, in cross section, cap placement over the hole of the substrate of FIG. 10;

FIG. 12 is a schematic drawing illustrating, in cross section, filling of the structure of FIG. 11;

FIG. 13 is a schematic drawing showing the different layers and component of a structure in accordance with various embodiments having a 5×5 mm body size; and

FIG. 14 is a schematic drawing showing the different layers and component of a structure in accordance with various embodiments having a 4×4 mm body size.

### DETAILED DESCRIPTION

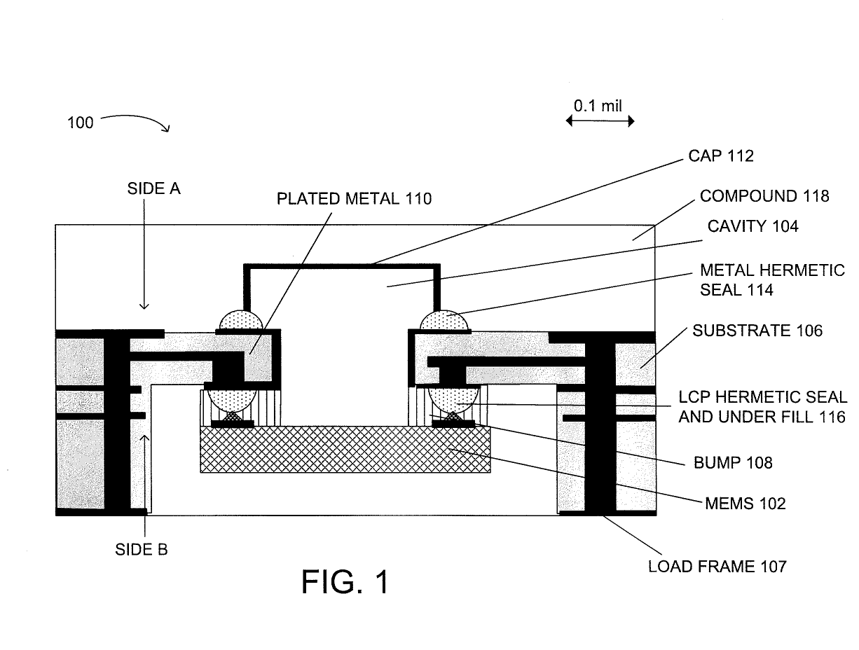

Methods in accordance with various embodiments of the invention may be utilized to fabricate chips with integrated MEMS devices. FIG. 1 shows a cross section of an exemplary structure 100 including a MEMS device 102 in a cavity 104. The structure includes a substrate 106, which may be a multi-layer organic laminated substrate with high glass transition temperature. Attached to the substrate is an etched lead frame 107. The MEMS device 102 may be, e.g., an accelerometer die, which, when in operation, transmits signals along the substrate 106. The MEMS device 102 is bumped and bonded to the bottom of the substrate 106 (labeled side B) underneath a recessed cavity. Plated bumps or stud bumps 108 serve to separate the MEMS device 102 from the substrate 106. The substrate 106 may form the cavity walls or, as shown, a portion of the cavity walls, thereby reducing the overall height of the completed structure. Plated metal 110 may line the cavity walls formed by the substrate 106 to improve hermetic sealing. A metal cap 112, soldered onto the top surface (labeled side A) of the substrate 106, covers the cavity hole in the substrate 106, and a metal seal ring 114, formed during the soldering process, seals the rim of the cap 112. On side B, a liquid crystal polymer (LCP) under-fill provides the hermetic seal around the MEMS device 102. The hermetic seal is further stabilized with a filling compound 118 that surrounds the substrate and the cavity 104 encapsulated by the MEMS device 102, the substrate 106, and the cap 112. The cavity 104 may be evacuated, or filled with a pressurized gas. While the structure 100 shown in FIG. 1 includes only a single MEMS device 102, this structure may be a portion of a larger module combining different devices, such as accelerometers, magnetometers, GPS devices, and discrete components into one package.

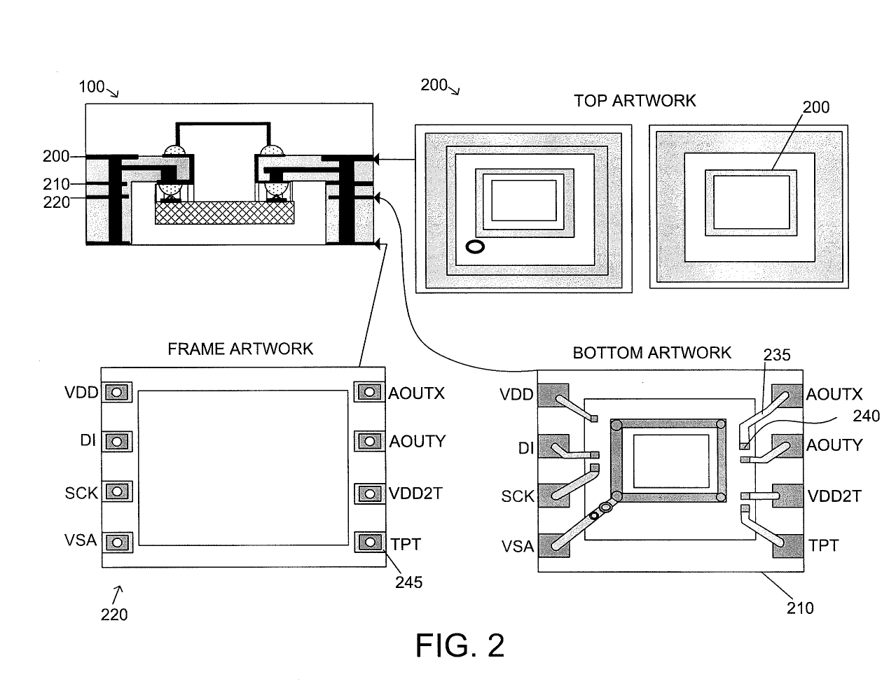

FIG. 2 illustrates in more detail an exemplary structure of the substrate 106, as it may be used in printed-circuit-board (PCB) manufacturing in accordance with embodiments of the invention. The substrate 106 includes an organic sheet having copper disposed on both sides. Standard PCB manufacturing processes (such as, e.g., photolithography) may be employed to create the artwork 200, 210 of the top and bottom copper layers, respectively. Similar processes may be used to create the artwork 220 for the lead frame 107, which may be metalized with copper and tin. The top artwork 200 includes large metalized areas for soldering the cap 112 to the substrate 106 and achieving a hermetic seal. The upper right subfigure shows the landed position 230 of the cap 112. Cap size and position may vary dependent on the specific application. The bottom artwork 210 features traces 235 for routing signals from the signal pins 240 to pads 245 in the frame. The upper left subfigure illustrates how the top, bottom, and frame artworks 200, 210, 220 are integrated into the substrate 106.

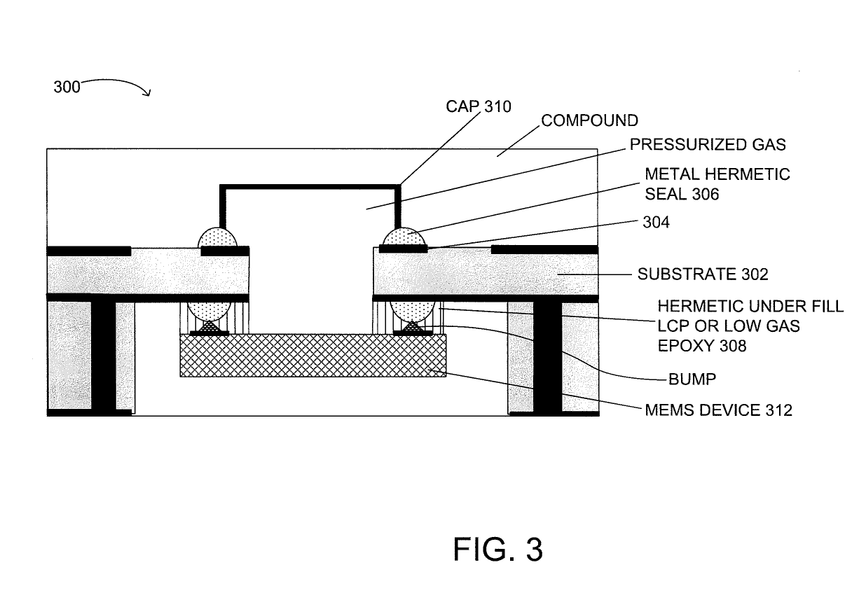

Various modifications of the structure 100 shown in FIG. 1 are contemplated. For example, in some embodiments, such as structure 300 shown in FIG. 3, a substrate 302 without end-metallization may be used. The substrate 302 is typically a low-outgassing substrate. A metallic ring layer 304 around the rim of the cavity hole may facilitate the connection of the substrate 302 to the metal seal 306. LCP under-fill 308 may used with both the hermetic seal of metal cap 310 and the MEMS device 312.

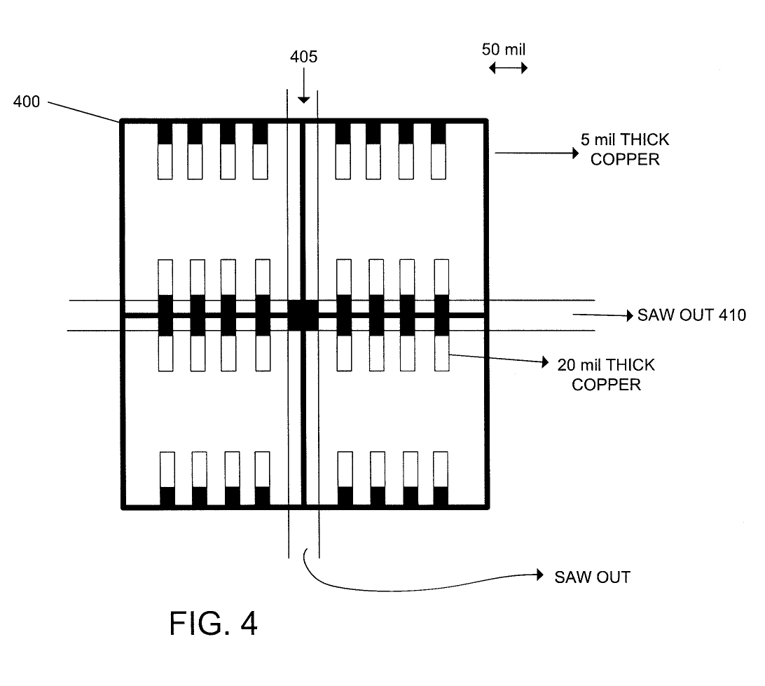

The manufacture of structures such as the ones shown in FIGS. 1 and 3 is readily scalable. This is illustrated in FIG. 4, which shows the etched lead frames of four devices arranged in a 2×2-array on a single substrate 400. Once the devices are built on this substrate, the structure may be saw-cut into four individual devices along saw-cut lines 405, 410.

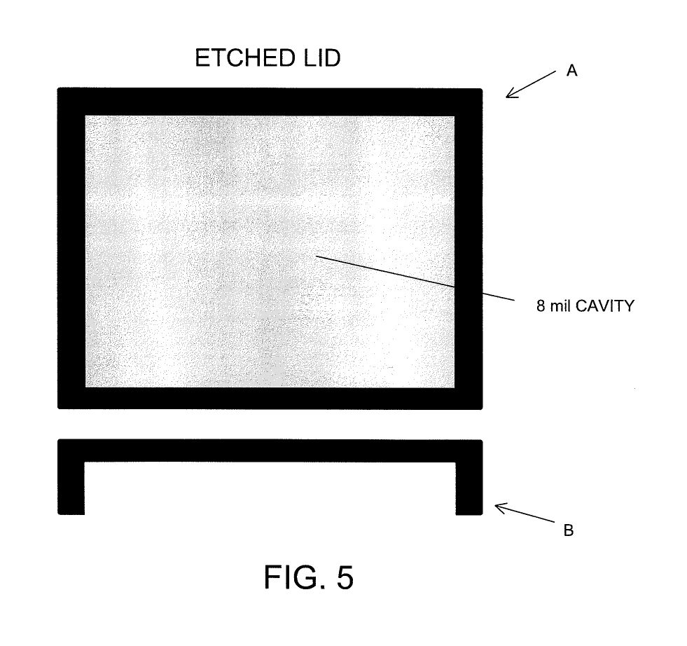

FIG. 5 illustrates, in a top view A and a side view B, the geometry and relative dimensions of a cap that may be used to cover a cavity hole. A typical cap may be quadratic in shape and have lengths of about 8 mm. Caps may be manufactured by etching cavities into a metal sheet, using conventional etching techniques. Alternatively, the caps may be punched out of metal sheets. For mass-manufacture, arrays of such cavities may be created in a single sheet.

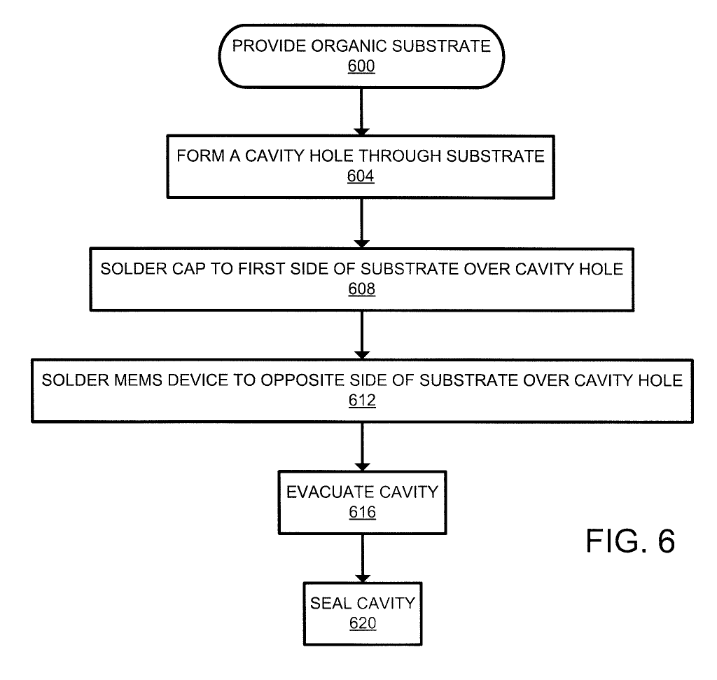

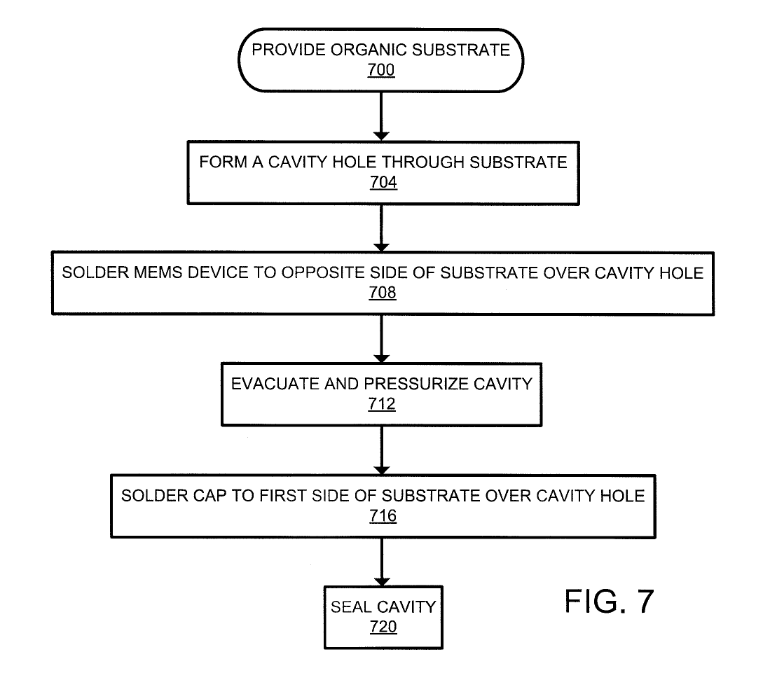

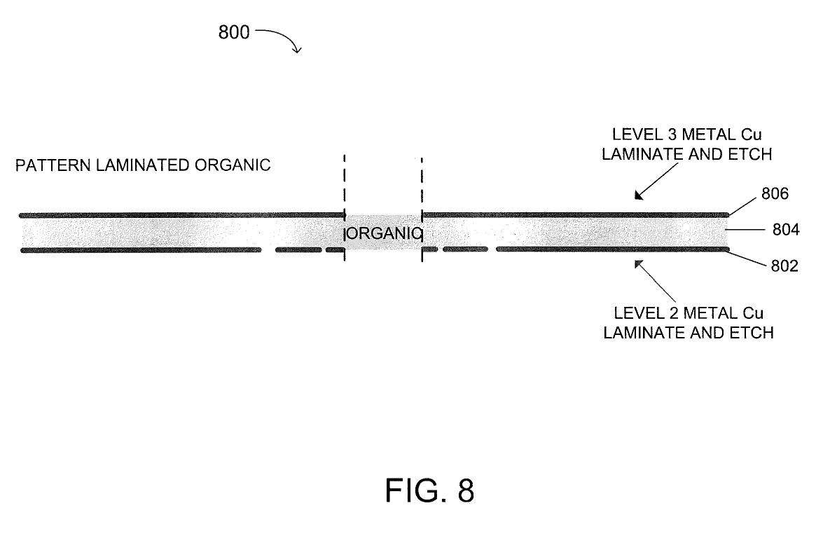

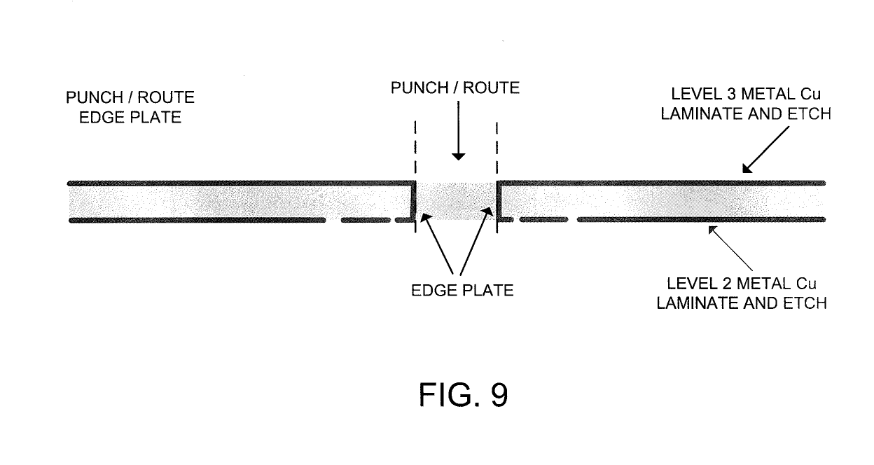

FIGS. 6 and 7 illustrate exemplary process sequences for fabricating MEMS packages, such as those shown in FIGS. 1 and 3. The two sequences differ in the order in which the different components of the structure are assembled. Referring to FIG. 6, a method for integrating a MEMS device in a cavity involves, as a first step 600, providing an organic substrate. As illustrated in FIG. 8, the substrate 800 (corresponding to substrate 106 in FIG. 1 and substrate 306 in FIG. 3) may be laminated and include a metallic bottom layer 802, an organic middle layer 804, and a metallic top layer 806. The top and bottom layers 802, 806 are patterned, for example, as illustrated in FIG. 2. In a second step 604, illustrated in more detail in FIG. 9, a cavity hole is formed, using, for example, a router, a laser-cutter, or a hole puncher. An edge-plating process may then be employed to metalize the edge surface of the cavity hole. Plating may be adjusted and/or optimized to produce a non-soluble metal surface sufficient to maintain a hermetic level seal on the top ring, bottom ring, and wall of the cavity hole. Edge-plating is generally not necessary if a low-outgassing substrate is used. Around the metal seal ring on the bottom surface (i.e., on side B), bond pads are patterned (see FIG. 2). These bond pads are connected to traces 235 for signal distribution. The ends of the traces are directly routed to larger bond pads 245 of the landed lead frame. Solder masks may be applied to both sides of the substrate to provide solder confinement, and trace isolation for side B. In the regions surrounding the cavity hole, where the hermetic seal will be formed, solder mask is lacking so that solder mask out-gassing into the cavity is avoided.

Once the substrate is prepared, the cap is soldered to the top surface (side A) of the substrate over the cavity hole (step 608). This step involves applying solder paste to side A, placing and aligning the cap, reflow-soldering the cap to the substrate, and curing. The solder paste may be dispensed or screen-printed onto the substrate. The cap may be aligned with a pick. Solder is typically selected based on the substrate. For gold-plated substrates, conventional solder may be used. In embodiments, where the presence of nickel (which normally provides a barrier between the gold and copper layers) impacts sensor performance, i.e., where a gold-free substrate is required, SnSbCu solder, or an equivalent solder, may be used instead. Reflow-soldering may be conducted at temperatures between about 260° C. and about 340° C. Since SnSbCu solder, or an equivalent solder, has a melting point of around 260° C., this allows an end-customer of the package structure to later reflow by a secondary green solder process (typically, a SnAgCu process).

In the next step 612, the MEMS device is soldered to the bottom surface of the substrate (side B) opposite the cap. Further, the lead frame is soldered to the bottom surface. This process is carried out inside a chamber that includes a dispensing device and heater. The chamber may be atmospherically regulated to provide either vacuum or pressure with a gas of choice, depending on the requirements of the MEMS sensor. Similarly to step 608, soldering involves applying solder paste to side B, placing the MEMS die and etched lead frame on the substrate and aligning them, and reflowing at temperatures between about 260° C. and about 340° C. The MEMS device is separated from the substrate by stud bumps or plated bumps 108 (e.g., from copper or gold), as illustrated in FIG. 1. The height of the bumps and solder together results in an overall spacing between substrate and MEMS device that may be adjusted to less than or about 50 μm. This spacing provides a path for atmospheric equalization.

In step 616, the chamber is evacuated. Thereafter, in step 620, the cavity is sealed. To create a hermetic seal, a low-outgassing epoxy or, alternatively, a liquid crystal polymer may be dispensed around the edge of the MEMS device on side B to form an underfill 116. The dispense process may be adjusted with heat and pressure to ensure that capillary action wicks the underfill around the bond pads between the substrate surface and the MEMS die surface. In particular, by controlling the heat of the substrate, it is possible to ensure that the underfill wicks to the edge of the substrate opening, but not beyond onto the surface of the MEMS device. The device may then be cured in the chamber in batch process. Side B may be finished by dispensing fill material around the etched lead frame. Finally, the substrate may be cut using, e.g., a wafer dicing saw, to singularize the encapsulated MEMS devices.

The method described above may be varied in several ways. For example, in some embodiments, the bottom metal seal ring may receive a secondary plating that forms a raised ridge and acts as an underfill edge stop. The plating may be approximately 25 μm high. Further, in certain embodiments, the cavity is sealed by placing a pre-formed low-outgassing epoxy ring or liquid crystal polymer ring on side B of the substrate after screen printing and before die placement. During the reflow process, both this ring and the solder will seal. This modification allows for a secondary underfill on the die with separate controlled parameters. Similarly, the cap may be attached by placing a pre-formed low-outgassing epoxy ring or liquid crystal polymer on side A of the substrate after screen printing and before cap placement.

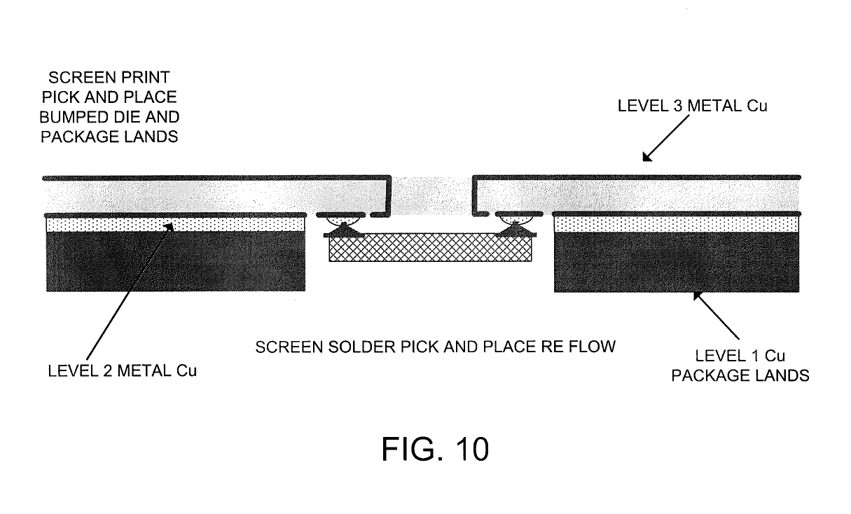

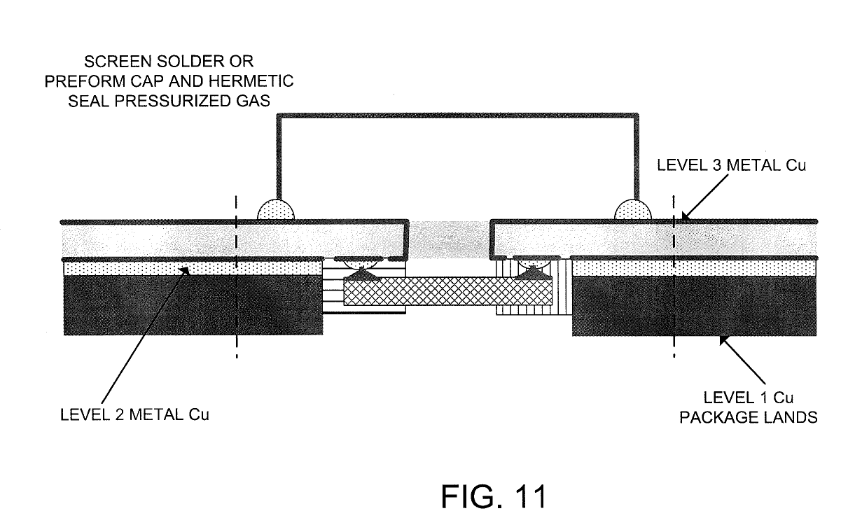

Referring now to FIG. 7, a method for integrating a MEMS device in a pressurized cavity involves, again, providing an organic substrate (step 700) and forming a cavity hole in the substrate (step 704), as illustrated in FIGS. 8 and 9. Next, the MEMS device is soldered to side B of the substrate (step 708), as illustrated in FIG. 10. SnSbCu solder, or similar solder paste, with a melting point of about 260° C. may be applied to side B by screen printing. The solder paste serves to make electrical contacts. The stud-bumped or plated MEMS device is pick-and-placed onto the substrate over the punched or routed hole. The lead frame is likewise placed on and aligned with the substrate. The substrate with the placed MEMS device and lead frame is then reflowed at temperatures between about 260° C. and about 340° C., whereby the lead frame and MEMS die are soldered to the substrate. Subsequently, the die may be underfilled with a low-outgassing epoxy or a liquid crystal polymer, exploiting capillary action to flow the underfill between the die and the substrate until it meets the metal seal ring and cavity hole (see FIG. 11). The underfill may then be cured by placing the substrate assembly into a reflow or conventional oven. After the MEMS device is soldered to the substrate, the assembly may be optically inspected, and cleaned using a oxygen plasma ashing, or a similar process, to remove organic contaminates.

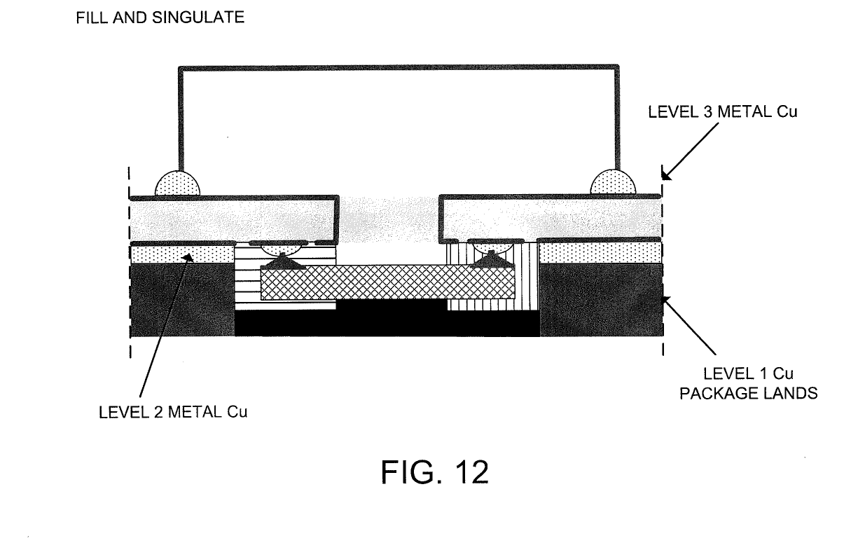

Next, in step 712, the entire assembly, as shown in FIG. 11, is placed under vacuum or pressure inside a pressure chamber that mounted onto a hot plate or heater. The vacuum or pressure is set to the required operating pressure of the MEMS device, corrected for the process temperature. Then, step 716, side A is processed. First, SnSbCu solder or a similar solder is screen-printed onto either the substrate or the cap array. The cap array is then aligned with the substrate, using alignment pins, and separated from the substrate with SnSbCu solder wire or balls of greater height than the screen-printed solder paste. The temperature is raised with the heater or hot plate beyond the melting point of the solder wire or balls, causing the wire or balls to melt along with the solder paste, thereby sealing the pressurized gas within the cavity. The heat is then removed, and the solder seal solidifies, forming a hermetic (or nearly hermetic) seal (step 720). As illustrated in FIG. 12, compound may then be added to impart rigidity and mechanical stability on the package. Advantageously for later mounting on a board, the additional compound provides the finished module with a flat top surface, even if multiple devices of various heights are integrated into the substrate. Finally, the assembly may be diced into individual encapsulated MEMS structures.

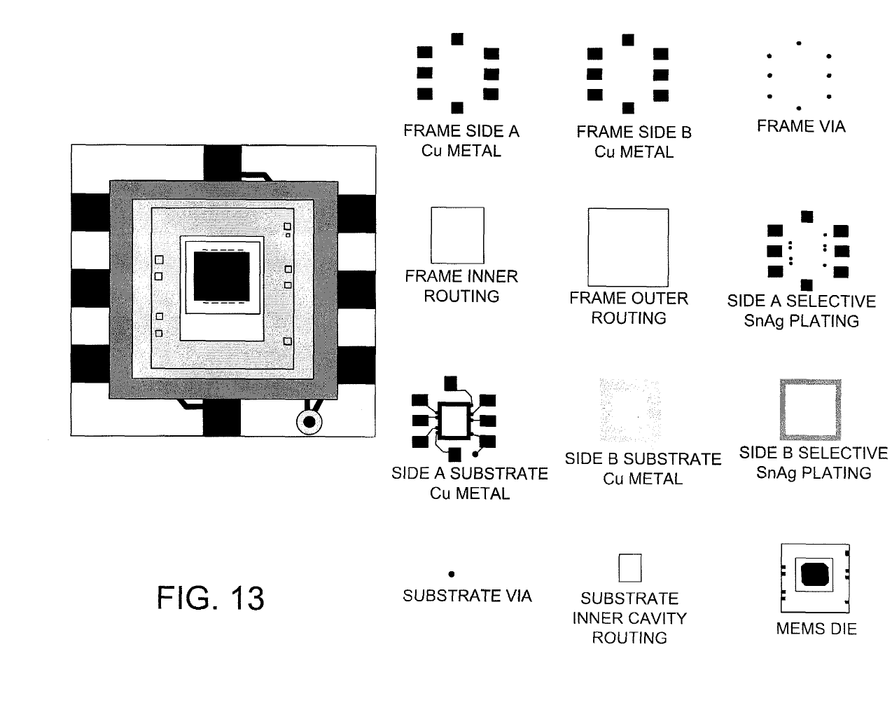

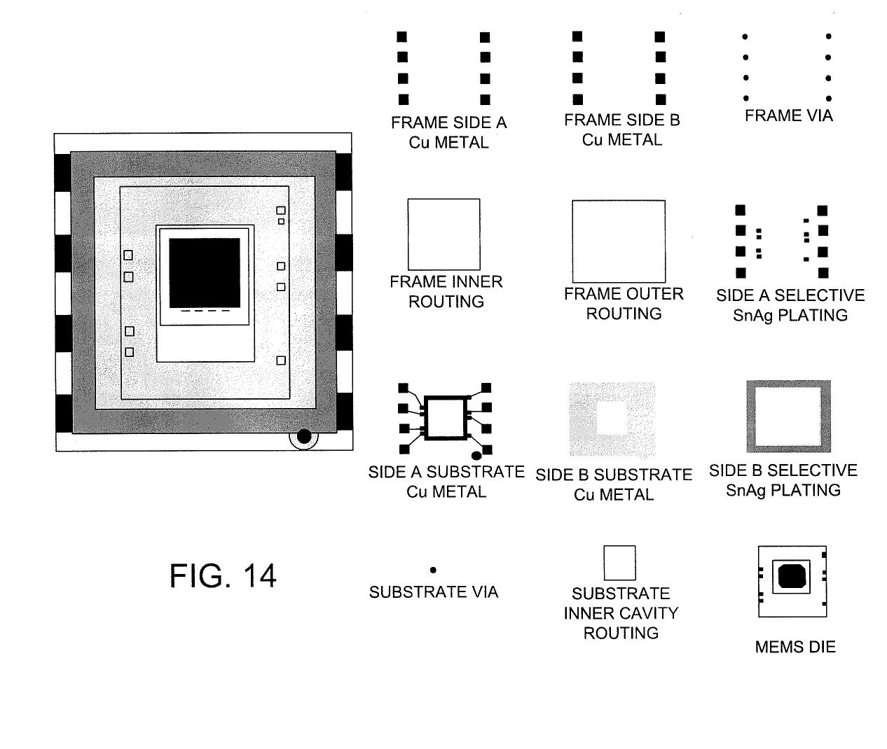

FIGS. 13 and 14 show the various substrate layers and components of the entire package. The specific design is adjusted for package size. For example, FIG. 13 illustrates the layers of a structure having a body size of 5 mm×5 mm. FIG. 14 shows the layers of an otherwise similar structure with a body size of only 4 mm×4 mm. Such as smaller package may be suitable for use in cell phones, and for other applications that require small dimensions. As illustrated, the body size of the package may be shrunk by implementing appropriate design changes.

Having described certain embodiments of the invention, it will be apparent to those of ordinary skill in the art that other embodiments incorporating the concepts disclosed herein may be used without departing from the spirit and scope of the invention. Accordingly, the described embodiments are to be considered in all respects as only illustrative and not restrictive.

What is claimed is:

1. A method for integrating a micro-electromechanical sensor (MEMS) device into an organic chip scale package, the method comprising the steps of:
(a) providing a high glass transition temperature multi-layer organic laminated substrate;
(b) forming a cavity hole through the substrate;
(c) soldering a cap to a first side of the substrate over the cavity hole;
(d) placing the MEMS device on a second side of the substrate under the cavity hole, thereby forming a cavity; and
(e) sealing the cavity.

2. The method of claim 1 wherein step (b) comprises at least one of routing, laser cutting, or punching through a patterned metal ring.

3. The method of claim 1 further comprising the step of edge-plating a metal layer onto an edge surface of the cavity hole.

4. The method of claim 3 further comprising the step of plating a second metal layer onto the edge surface at a second side of the substrate.

5. The method of claim 1 wherein step (c) comprises reflow soldering at a temperature in the range from about 260° C. to about 340° C.

6. The method of claim 1 further comprising, before step (d), applying solder paste to the second side of the substrate.

7. The method of claim 1 further comprising, after step (d), evacuating the cavity.

8. The method of claim 1 further comprising, after step (d), pressurizing the cavity with a selected pressurizing gas.

9. The method of claim 1 wherein step (e) comprises dispensing low-outgassing epoxy around an edge of the MEMS device.

10. The method of claim 1 wherein step (e) comprises dispensing liquid crystal polymer around an edge of the MEMS device.

11. The method of claim 1 further comprising, before step (d), placing a preformed low-outgassing epoxy ring around the hole on a second side of the substrate.

12. The method of claim 1 further comprising, before step (d), placing a preformed crystal polymer ring around the hole on a second side of the substrate.

13. The method of claim 1 further comprising placing a preformed low-outgassing epoxy ring or liquid crystal polymer on the first side of the substrate.

14. The method of claim 1 further comprising placing a preformed liquid crystal polymer ring or liquid crystal polymer on the first side of the substrate.

15. A method for integrating a micro-electromechanical sensor (MEMS) device into an organic chip scale package, the method comprising the steps of:
(a) providing a high glass transition temperature multi-layer organic laminated substrate;
(b) forming a cavity hole through the substrate;
(c) soldering the MEMS device to a second side of the substrate under the cavity hole;
(d) placing a cap on a first side of the substrate over the cavity hole, thereby forming a cavity; and
(e) sealing the cavity.

16. The method of claim 15 further comprising, after step (c), underfilling the MEMS device with a low-outgassing epoxy.

17. The method of claim 15 further comprising, after step (c), underfilling the MEMS device with a liquid crystal polymer.

18. The method of claim 15 further comprising, before step (d), cleaning the substrate and MEMS device using oxygen plasma ashing.

19. The method of claim 15 further comprising evacuating the cavity.

20. The method of claim 15 further comprising pressurizing the cavity with a selected cavity gas.
